(19) United States
(12) Patent Application Publication
(10) Pub. No.: US 2015/0214066 A1
(43) Pub. Date: Jul. 30, 2015

(54) METHOD FOR MATERIAL REMOVAL IN DRY ETCH REACTOR

(71) Applicant: Applied Materials, Inc., Santa Clara, CA (US)

(72) Inventors: Olivier Luere, Sunnyvale, CA (US); Srinivas D. Nemani, Sunnyvale, CA (US); Sean S. Kang, San Ramon, CA (US)

(73) Assignee: Applied Materials, Inc., Santa Clara, CA (US)

(21) Appl. No.: 14/164,679

(22) Filed: Jan. 27, 2014

(51) Int. Cl. H01L 21/311; H01L 21/033

(52) U.S. Cl. CPC H01L 21/31116; H01L 21/31144; H01L 21/0332

(57) ABSTRACT

Embodiments of the technology include a semiconductor patterning method. The method may include forming a layer of masking material on regions of dielectric material above a semiconductor substrate. The method may include forming a trench through the masking material. This transformation may expose at least a portion of the dielectric material. The method may include forming a protective layer over the exposed portion of the dielectric material. The method may involve removing the masking material from the semiconductor substrate.

### TECHNICAL FIELD

The present technology relates to semiconductor systems, processes, and equipment. More specifically, the present technology relates to systems and methods for reducing film contamination and equipment degradation.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, dry etches may damage structures during the etch if a high enough selectivity is not achievable.

Thus, there is a need for improved systems and methods that can be used to produce high quality devices and structures. These and other needs are addressed by the present technology.

### SUMMARY

As semiconductor devices become smaller, patterning these devices may become more challenging. Smaller features may be harder to define. This may be a result of the decreased size or of more stringent tolerances needed for performance, reliability, and manufacturing throughput. The methods described below may provide an improved patterning process.

Embodiments of the technology include a semiconductor patterning method. The method may include forming a layer of masking material on regions of dielectric material above a semiconductor substrate. The method may include forming a trench through the masking material. This transformation may expose at least a portion of the dielectric material. The method may include forming a protective layer over the exposed portion of the dielectric material. The method may involve removing the masking material from the semiconductor substrate.

In embodiments, a semiconductor patterning method may involve forming a masking layer on top of underlying material. The masking layer has a top surface. The method may include forming a trench through the masking layer. This trench may expose a portion of the underlying material. The method may involve forming a protective layer on the top surface of the masking layer. The method may include removing a portion of the protective layer. The method may include removing the masking layer by flowing a first gas through a remote plasma source and showerhead. The removal of the masking layer may retain the portion of the underlying material.

A method of patterning features on a semiconductor substrate may include forming a dielectric layer. The method may include forming a mask layer above the dielectric layer. The mask layer has a top surface. The method may involve patterning the mask layer of the dielectric layer to form a trench in the dielectric layer. The trench may have a sidewall made up of dielectric material. The method may involve forming a carbon-containing protective layer on the top surface of the mask layer. The formation of the carbon-containing protective layer may include striking a first plasma in a first substrate-processing region and flowing a carbon-containing gas through this plasma. The method may involve removing substantially all of the carbon-containing protective layer from the top surface of the mask layer while retaining a portion or substantially all of the protective layer on the sidewall. The removal of the protective layer may involve striking a second plasma in a second substrate-processing region, flowing a mixture of gases comprising hydrogen and nitrogen through the second plasma to form an energized mixture of gases, and reacting the energized mixture of gases with the protective layer. The method may involve removing the mask layer with a dry process while retaining the dielectric layer from the sidewall. The removal of the mask layer may involve striking a third plasma in a region separated from the semiconductor substrate by a showerhead, flowing a fluorine-containing gas through the third plasma and showerhead plasma effluents, and reacting the plasma effluents with the mask layer.

Such technology may provide numerous benefits over conventional systems and techniques. This technology may avoid wet etching the masking material and associated characteristics of a wet etch, particularly at smaller and smaller characteristic dimensions. This technology may provide a method of dry etching a masking material even if a high selectivity to the masking material over an underlying material may not be achievable. For example, the methods presented herein may preserve patterning profiles of the underlying material after removing the masking material. The methods may also allow for narrower features in the underlying material. Another benefit may be to reduce the number of different types of processing equipment or processing operations needed in manufacturing. These or other benefits may result in increasing throughput. In addition, device performance, including speed, reliability, and power consumption, may be improved. These and other embodiments, along with many of their advantages and features, are described in more detail in conjunction with the below description and attached figures.

### DESCRIPTION OF THE DRAWINGS

A further understanding of the nature and advantages of the disclosed technology may be realized by reference to the remaining portions of the specification and the drawings.

FIGS. 1A-1F show cross-sections of a semiconductor substrate and other layers according to embodiments of the present invention.

FIG. 2 shows a method of patterning a semiconductor substrate according to embodiments of the present invention.

FIG. 3 shows a method of patterning a semiconductor substrate according to embodiments of the present invention.

FIG. 4 shows a method of patterning a semiconductor substrate according to embodiments of the present invention

FIG. 5 shows a top plan view of one embodiment of an exemplary processing tool according to embodiments of the present invention.

FIGS. 6A and 6B show cross-sectional views of an exemplary processing chamber according to embodiments of the present invention.

FIG. 7 shows a schematic view of an exemplary showerhead configuration according to embodiments of the present invention.

### DETAILED DESCRIPTION

Semiconductor patterning may involve patterning an upper layer along with an underlying layer. Semiconductor processing technology may also remove at least a portion of the upper layer while retaining the underlying layer. Conventional semiconductor processing technology may remove at least some of the upper layer but may still affect the underlying layer. The underlying layer may itself be etched partially away, thereby changing the initially patterned profile. Furthermore, the removal of the upper layer may also deposit contaminants on the underlying layer or affect the structural, electrical, or other properties of the underlying layer. Conventional processing may also require additional processing operations or equipment. These methods may detrimentally degrade the performance of the semiconductor device. Such methods may include wet etching of masking layers. Wet etching may result in damaging remaining materials when liquid is removed from semiconductor structures. Capillary and surface tension forces may cause such structures to bend or collapse. Embodiments of the technology described herein may avoid the disadvantages associated with wet etch chemistry and may instead use dry etch chemistry.

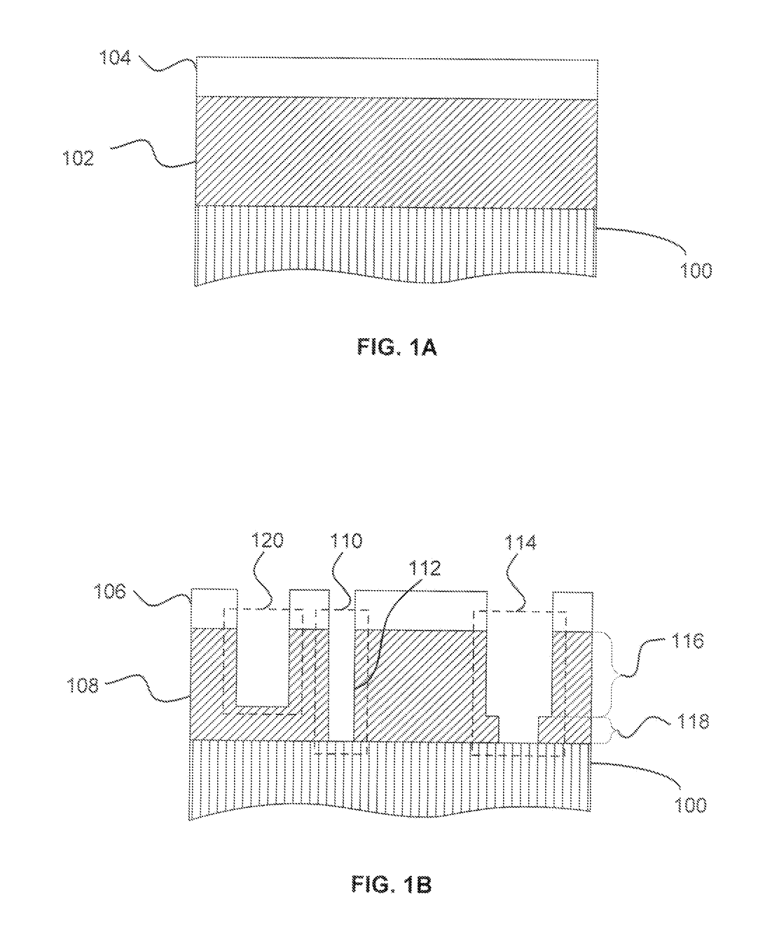

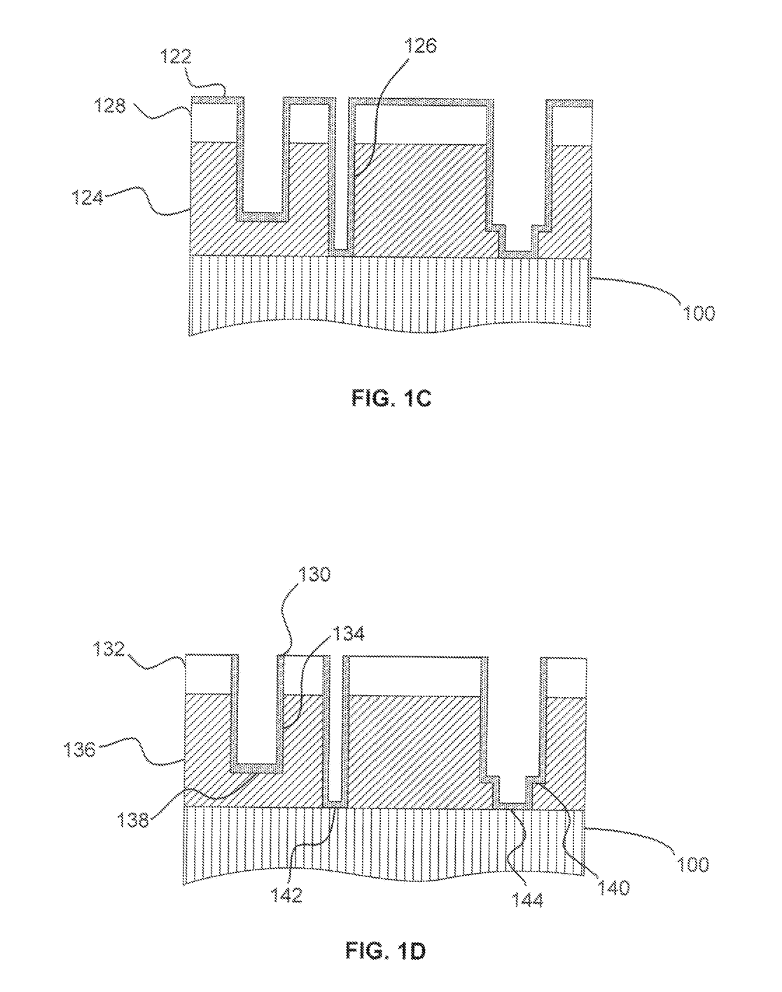

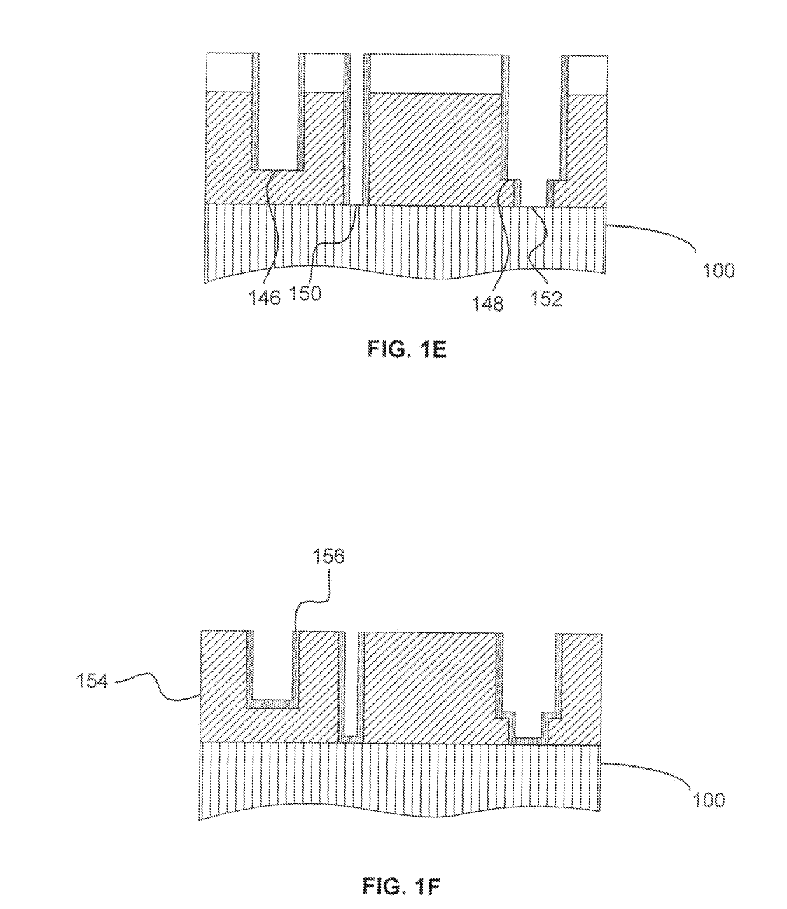

In an embodiment, the semiconductor patterning method may include forming a masking layer on regions of dielectric material above a semiconductor substrate. A masking layer may be composed of material that is not easily etched by a process that etches the dielectric material. FIG. 1A illustrates an embodiment of the present technology. A dielectric material 102 may be above a layer 100. The layer 100 may be the semiconductor substrate and additional processing layers, which may include patterned features in the layers. Layer 100 may include an etch stop layer or a layer to protect layers underneath. Such a layer may contain silicon, carbon, and nitrogen. A masking layer 104 may be on top of the dielectric material 102. To be “on top of” the dielectric layer is defined as being on the opposite side of the dielectric layer as the semiconductor substrate and layer 100. FIGS. 1A-1F are oriented such that the “top” side of the semiconductor substrate would be toward the top of the figure. Descriptions of methods below will adopt this convention. However, one of skill would recognize that a semiconductor substrate may be processed at various orientations such that the “top” side may not always face away from the floor.

The dielectric material may contain silicon and oxygen species, and may include silicon dioxide. The dielectric material may be a low-k dielectric. The low-k dielectric may be material with a dielectric constant below about 3.0, below about 2.0, or below about 1.0 in embodiments. The masking layer may be a metal hard mask, such as titanium nitride. The masking layer may have a top surface. A dry etch that removes the masking layer material may not be selective to the masking layer material over the dielectric material. Accordingly, a dry etch of the masking layer may remove or damage the dielectric material.

The method may include forming a trench through the masking material, where the transformation exposes at least a portion of the dielectric material. Turning to FIG. 1B, the masking material 106 has been patterned or etched, according to embodiments of the present invention. The dielectric material 108 may define a trench 110. A trench may have a sidewall 112, and the sidewall may comprise the dielectric material 108. The sidewall may have a profile, and the profile may include the height of the sidewall, the angle of the sidewall, and the shape of sidewall. Trench 110 may expose layer 100. A trench may have a variety of shapes and profiles, as shown with trench 114, for example. Trench 114 may include an upper section 116 and a lower section 118. The lower section 118 of the trench 114 may be another trench or a via. Trench 120 shows that a trench may not expose layer 100 but only the dielectric material 108.

The method may involve forming a protective layer over the exposed portion of the dielectric material. Turning to FIG. 1C, a protective layer 122 may cover parts of the dielectric material 124. A section of the protective layer 122 may cover some, substantially all, or all of the sidewall 126. The protective layer may contain carbon. Additionally, the protective layer may also be a passivation layer. Forming the protective layer may include striking a plasma in a substrate-processing region and flowing a gas through the plasma. The gas may contain carbon, and the gas may be methane, a fluorocarbon species (e.g., CH₂F₂, C₄F₆, C₄F₈), or mixtures thereof. The protective layer 122 formed may conformally coat the masking layer 128 and exposed dielectric material. The protective layer may non-conformally coat the masking layer and exposed dielectric material defining the trench. With non-conformal formation of the protective layer, the protective layer may be thicker in some areas and thinner in other areas, and the protective layer may overhang the corners of a trench.

The method may involve removing substantially all of the protective layer from the top surface of the layer of masking material. Turning to FIG. 1D, the protective layer 130 may be substantially removed from the top of the layer of masking material 132. The method may also retain a portion or substantially all of the section of protective layer 130 on the sidewall 134. In this case, the dielectric material 136 may still be covered in part or entirely by the protective layer 130. Removing the protective layer 130 may involve striking a plasma in a substrate-processing region, flowing a gas through the plasma to form an energized gas, and reacting the energized gas with the protective layer 130. The gas may contain hydrogen and nitrogen, including a mixture of H₂ and N₂. The removal operation may be highly selective to the protective layer over the masking layer, with the selectivity possibly being 100:1. The gas may be essentially free of oxygen. The presence of oxygen may result in an isotropic instead of anisotropic etching of the protective layer. The semiconductor substrate may be at a temperature around 110° C. during removal of the protective layer.

The removal of substantially all of the protective layer from the top surface of the layer of the masking material may retain portions of the protective layer in certain features. For example, protective layer 130 may cover areas 138, 140, 142, and 144. Alternatively, the removal of the protective layer could uniformly or nearly uniformly remove the layer from horizontal or nearly horizontal regions of trenches. For example, turning to FIG. 1E, the protective layer may be removed and may expose areas 146, 148, 150, and 152 according to embodiments of the present invention.

The method may include removing the masking material from a semiconductor substrate. Turning to FIG. 1F, the top surface of the dielectric layer 154 may be exposed. Any portion of the protective layer 156 contacting the masking layer may also be removed. Removing the masking layer may include striking a plasma in the region separated from the semiconductor substrate by a showerhead. The plasma may be a remote plasma source, and the removal may include flowing a gas through the plasma and the showerhead to form plasma effluents. The gas may contain fluorine. The gas may include NF₃, F₂, or XeF₂. These plasma effluents may include radical species and may exclude ions. In addition, ultraviolet light from the plasma may be minimized or may not reach the masking layer. The removal of the masking layer may involve reacting the plasma effluents with the masking material. The removal may be selective to the masking material over the protective layer, and the selectivity may be greater than or equal to about 50:1. The method may include removing substantially all of the protective layer from the sidewall. The removal of the protective layer from the sidewall may occur after the removal of the masking material and may occur at high temperatures to avoid damaging the dielectric material. Such temperatures may be around 300° C. or above according to embodiments. In embodiments, FIGS. 1A, 1B, 1C, 1D, and 1F may occur in the order listed. In other embodiments, FIGS. 1A, 1B, 1C, and 1E may occur in the order listed. The figures may also occur in other orders according to embodiments.

In embodiments and operations employing a remote plasma, an ion suppressor as described in the exemplary processing system section may be used to provide radical and/or neutral species tor selectively etching substrates. The ion suppressor may also be referred to as an ion suppression element. In embodiments, for example, the ion suppressor is used to filter fluorine- and hydrogen-containing plasma effluents to selectively etch the masking material. The ion suppressor may be included in each exemplary process described herein. Using the plasma effluents, an etch rate selectivity of the masking material (e.g., titanium nitride) to a wide variety of materials may be achieved.

The ion suppressor may be used to provide a reactive gas having a higher concentration of radicals than ions. The ion suppressor functions to dramatically reduce or substantially eliminate charged species traveling from the plasma generation region to the substrate. The electron temperature may be measured using a Langmuir probe in the substrate-processing region during excitation of a plasma in the remote plasma region on the other side of the ion suppressor. In embodiments, the electron temperature may be less than 0.5 eV, less than 0.45 eV, less than 0.4 eV, or less than 0.35 eV. These extremely low values for the electron temperature are enabled by the presence of the showerhead and/or the ion suppressor position between the substrate-processing region in the remote plasma region. Uncharged neutral and radical species may pass through the openings in the ion suppressor to react at the substrate. Because most of the charged panicles of the plasma are filtered or removed by the ion suppressor, the substrate is not necessarily biased during the etch process. Such a process using radicals and other neutral species can reduce plasma damage compared to conventional plasma etch processes that include sputtering and bombardment. The ion suppressor helps control the concentration of ionic species in the reaction region at a level that assists the process. Embodiments of the present invention may avoid the bending and peeling of small matures.

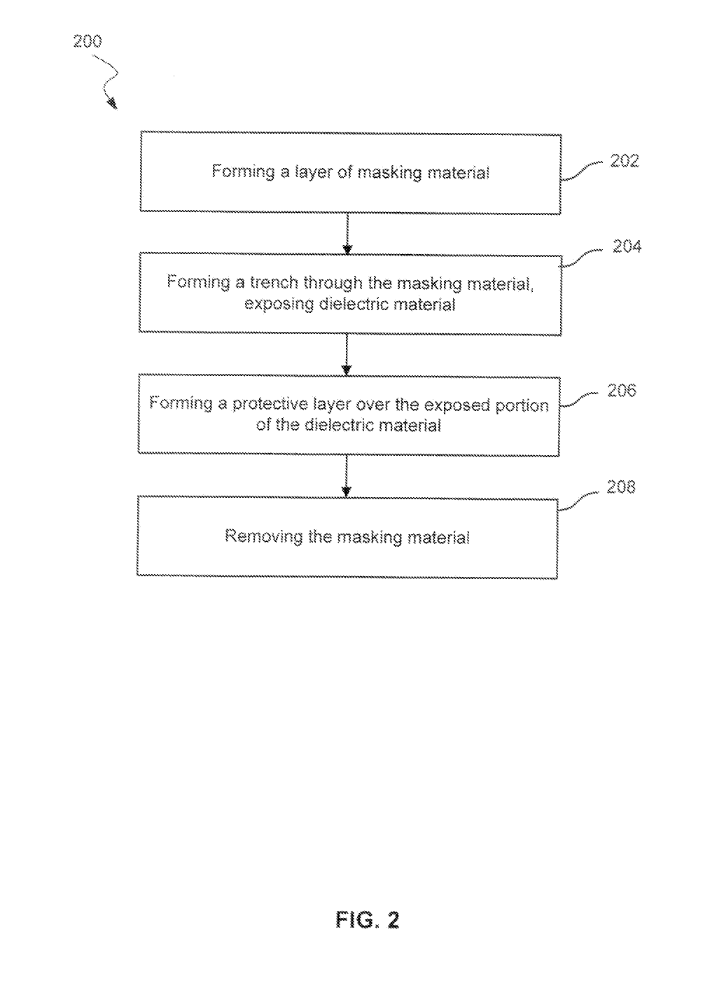

FIG. 2 shows a method 200 of semiconductor patterning, according to embodiments of the present invention. The method 200 may include forming a layer of masking material on regions of dielectric material above a semiconductor substrate 202. The method 200 may include forming a trench through the masking material, where the formation exposes at least a portion of the dielectric material 204. The method 200 may include forming a protective layer over the exposed portion of the dielectric material 206, and the method 200 may include removing the masking material 208.

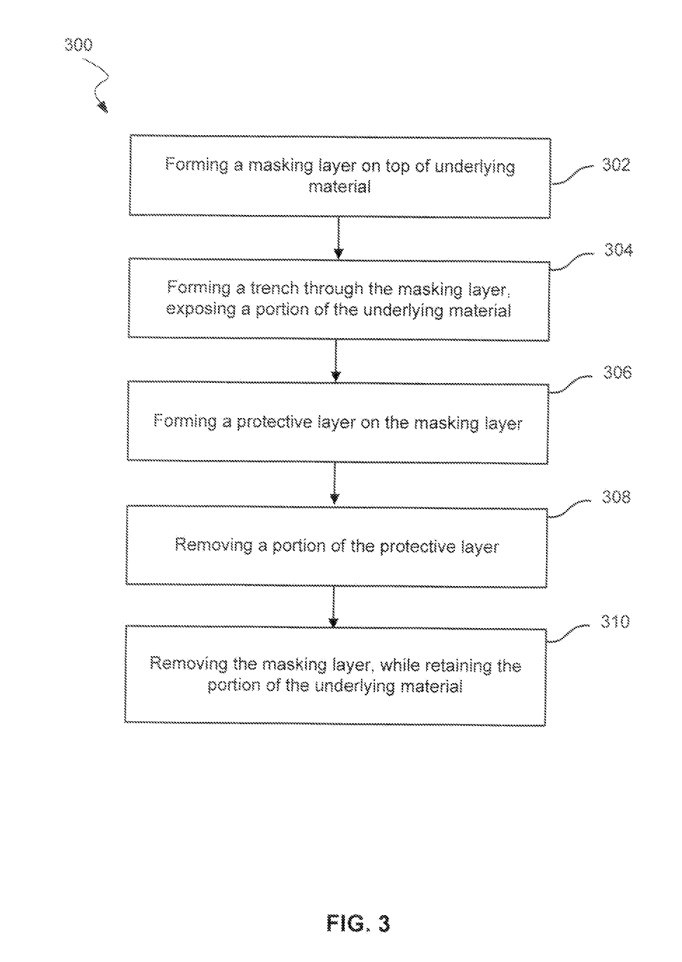

Turning to FIG. 3, the figure shows a method 300 of patterning a semiconductor substrate, according to embodiments of the present invention. The semiconductor patterning method 300 may include forming a masking layer on top of underlying material, where the masking layer has a top surface 302.

The method 300 may encompass forming a trench through the masking layer, where the formation of the trench exposes a portion of the underlying material 304. The trench may have a bottom, where the bottom may be composed of the underlying material or material from a layer underneath the layer of underlying material.

The method 300 may involve forming a protective layer on at least the top surface of the masking layer 300. Formation of the protective layer may form a section of the protective layer on the bottom of the trench and may form a second section of the protective layer on the top surface of the masking layer. The thickness of the first section of the protective layer may be the same or different as the thickness of the second section of the protective layer. The method may remove substantially all of the second section of the protective layer on the top surface of the masking layer and may retain a portion of the first section of the protective layer on the bottom of the trench. With returning reference to FIG. 1D, the protective layer 130 may be substantially retained on the bottom 142 of the trench. The bottom 142 of the trench may be continuously covered with the protective layer. Protective layer 130 may be substantially removed from above the masking material 132.

The method 300 may involve removing a portion of the protective layer 308. Removal of the portion of the protective layer may involve striking a plasma in a substrate-processing region. The removal may include flowing a second gas through the plasma to form an energized gas, and this energized gas may react with the protective layer.

The method 300 may include removing the masking layer, where the removal of the masking layer retains the portion of the underlying material 310. The removal operation may involve flowing a first gas through a remote plasma source and showerhead.

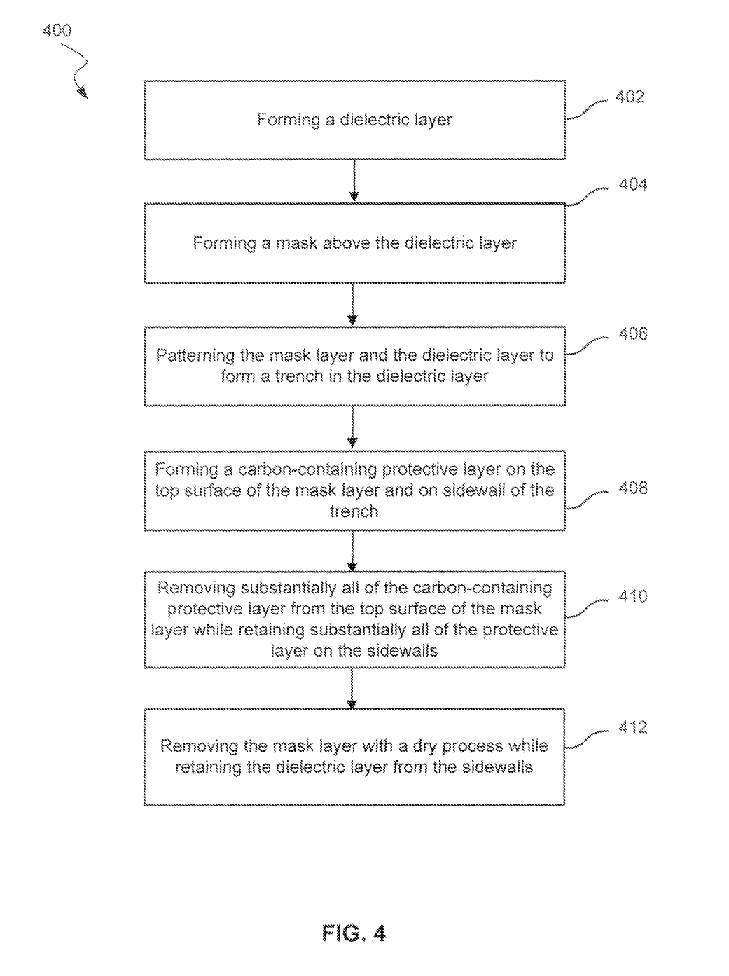

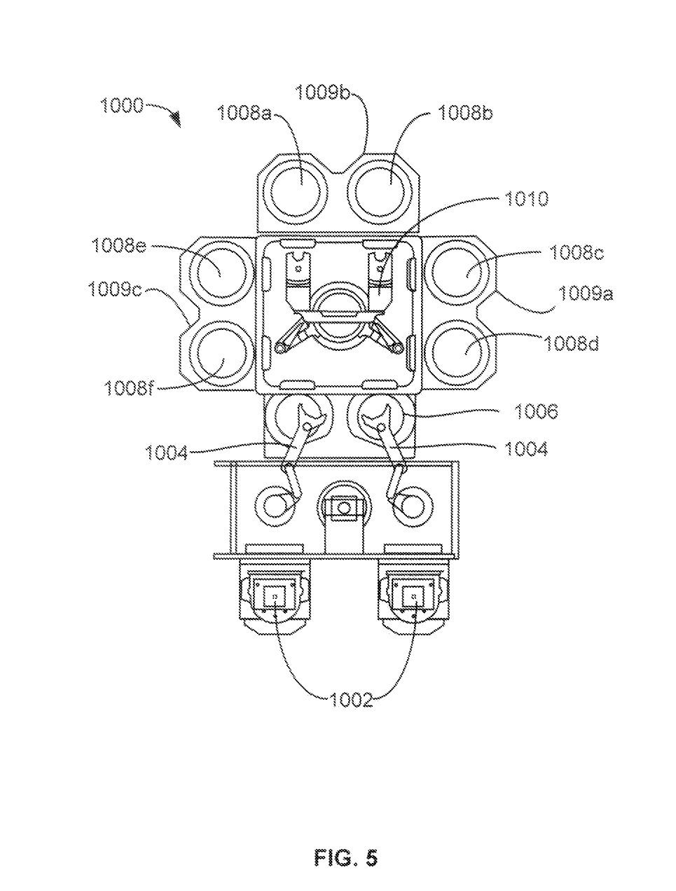

FIG. 4 illustrates a method 400 of patterning features on a semiconductor substrate that may include forming a dielectric layer 402, according to embodiments of the present invention. The method 400 may involve forming a mask layer above the dielectric layer 404. The mask layer may have a top surface. The method 400 may involve patterning the mask layer and the dielectric layer to form a trench in the dielectric layer 406. This trench may have a sidewall composed of dielectric material. The method may involve more than one trench.

The method 400 may include forming a carbon-containing protective layer on the top surface of the mask layer and on the sidewall of the trench 408. This formation may include striking a first plasma in a substrate-processing region. The formation may include flowing a carbon-containing gas through the first plasma.

The method 400 may involve removing substantially all of the carbon-containing protective layer front the top surface of the mask layer while retaining a portion of the protective layer on the sidewall of the trench 410. The portion of the protective layer may be continuous, and the portion of the protective layer may cover all or substantially all of the sidewall of the trench 410. The removal may include striking a second plasma in a second substrate-processing region. The first substrate-processing region may be the same as the second substrate-processing region or they may be different. The removal may include flowing a mixture of gases comprising hydrogen and nitrogen through the second plasma to form an energized mixture of gases. The removal may include reacting the energized mixture of gases with the protective layer.

The method 400 may include removing the mask layer with a dry process while retaining the dielectric layer defining the sidewall 412. The removal of the mask layer may include striking a third plasma in a region separated from the semiconductor substrate by showerhead. The removal of the mask layer may include flowing a fluorine-containing gas through the third plasma and showerhead to form plasma effluents. The removal may involve reacting the plasma effluents with the mask layer.

### Exemplary Processing System

Processing chambers that may implement embodiments of the present invention may be included within processing platforms such as the FRONTIER system, available from Applied Materials, Inc. of Santa Clara, Calif.

FIG. 5 shows a top plan view of one embodiment of a processing tool 1000 of deposition, etching, baking, and curing chambers according to disclosed embodiments. In the figure, a pair of front opening unified pods (FOUPs) 1002 supply substrates of a variety of sizes that are received by robotic arms 1004 and placed into a low pressure holding area 1006 before being placed into one of the substrate processing chambers 1008a-f, positioned in tandem sections 1009a-c. A second robotic arm 1010 may be used to transport the substrate wafers from the holding area 106 to the substrate processing chambers 1008a-f and back. Each substrate processing chamber 1008a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 1008a-f may include one or more system components for depositing, annealing, curing and/or etching a film on the substrate wafer. In one configuration, two pairs of the processing chamber, e.g., 1008c-d and 1008e-f, may be used to deposit material on the substrate, and the third pair of processing chambers, e.g., 1008a-b, may be used to etch the deposited film. In another configuration, all three pairs of chambers, e.g., 1008a-f, may be configured to etch a film on the substrate. Any one or more of the processes described may be carried out in chamber(s) separated from the fabrication system shown in different embodiments. Films may be dielectric, protective, or other material. It will be appreciated that additional configurations of deposition, etching, annealing, and curing chambers for films are contemplated by system 1000.

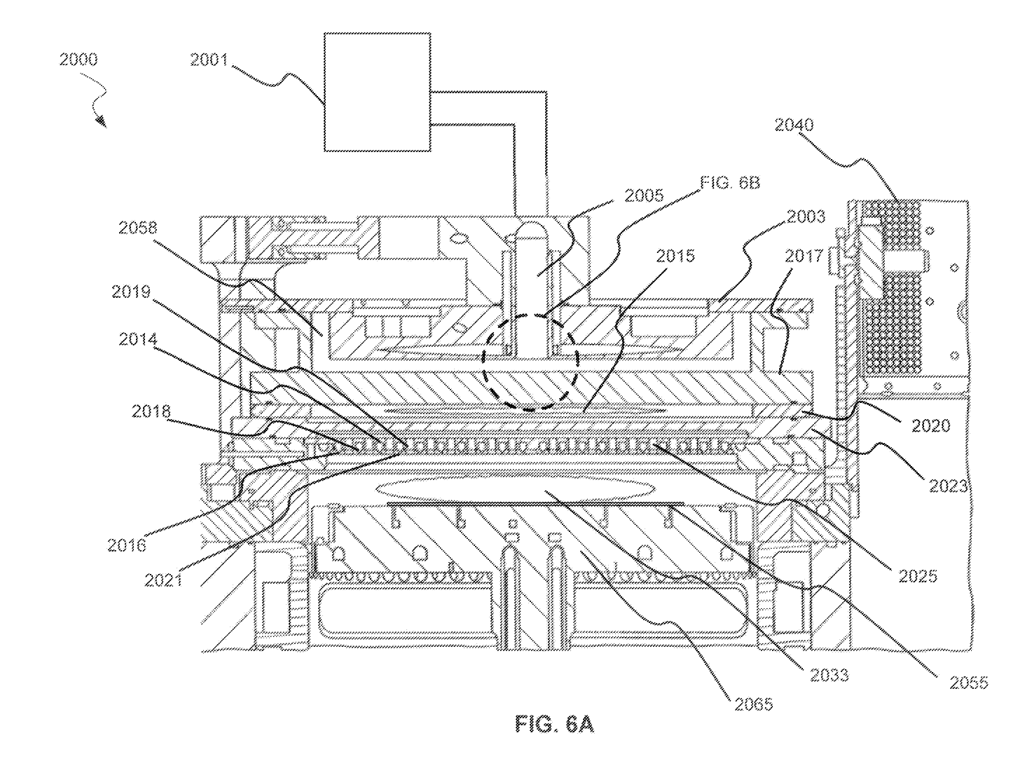

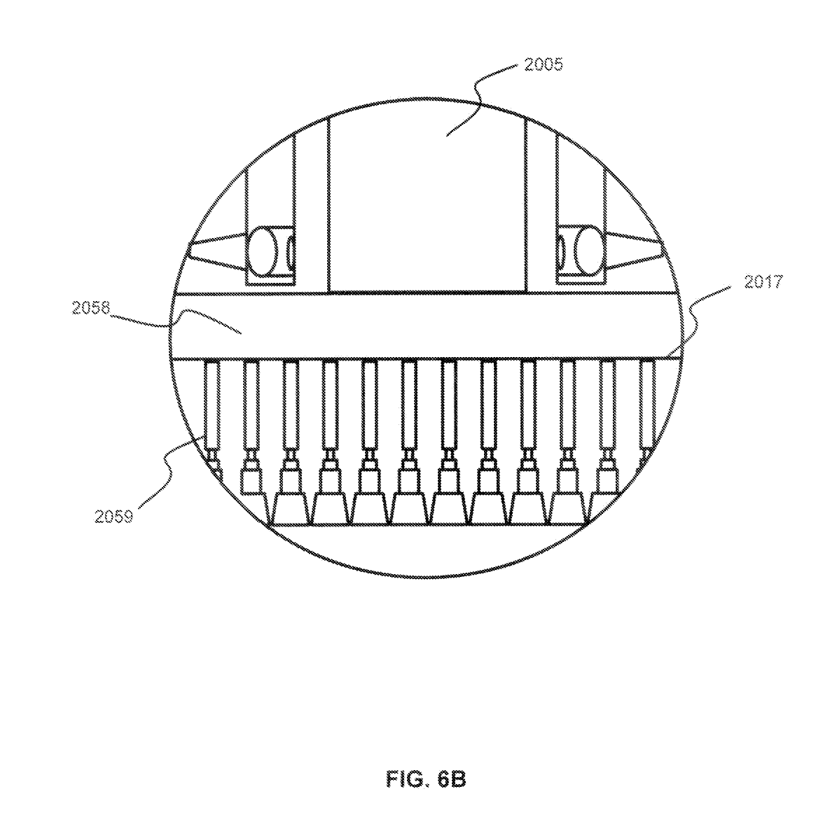

FIG. 6A shows a cross-sectional view of an exemplary process chamber section 2000 with partitioned plasma generation regions within the processing chamber. During film etching, e.g., silicon, polysilicon, silicon oxide, silicon nitride, silicon oxynitride, silicon oxycarbide, carbon-containing material, etc., a process gas may be flowed into the first plasma region 2015 through a gas inlet assembly 2005. A remote plasma system (EPS) unit 2001 may be included in the system, and may process a gas which then may travel through gas inlet assembly 2005. The inlet assembly 2005 may include two or more distinct gas supply channels where the second channel (not shown) may bypass the RPS unit 2001. Accordingly, in disclosed embodiments the precursor gases may be delivered to the processing chamber in an unexcited state. In another example, the first channel provided through the RPS may be used tor the process gas and the second channel bypassing the RPS may be used for a treatment gas in disclosed embodiments. The process gases may be excited within the RPS unit 2001 prior to entering the first plasma region 2015. Accordingly, a fluorine-containing precursor, for example, may pass through RPS 2001 or bypass the RPS unit in disclosed embodiments. Various other examples encompassed by this arrangement will be similarly understood.

A cooling plate 2003, faceplate 2017, ion suppressor 2023, showerhead 2025, and a substrate support 2065, having a substrate 2055 disposed thereon, are shown and may each be included according to disclosed embodiments. The pedestal 2065 may have a heat exchange channel through which a heat exchange fluid flows to control the temperature of the substrate. This configuration may allow the substrate 2055 temperature to be cooled or heated to maintain relatively low temperatures, such as between about −20° C. to about 200° C., or therebetween. The heat exchange fluid may comprise ethylene glycol and/or water. The wafer support platter of the pedestal 2065, which may comprise aluminum, ceramic, or a combination thereof, may also be resistively heated in order to achieve relatively high temperatures, such as from up to or about 100° C. to above or about 1100° C., using an embedded resistive heater element. The heating element may be formed within the pedestal as one or more loops, and an outer portion of the heater element may run adjacent to a perimeter of the support platter, while an inner portion runs on the path of a concentric circle having a smaller radius. The wiring to the heater element may pass through the stem of the pedestal 2065, which may be further configured to rotate.

The faceplate 2017 may be pyramidal, conical, or of another similar structure with a narrow top portion expanding to a wide bottom portion. The faceplate 2017 may additionally be flat as shown and include a plurality of through-channels used to distribute process gases. Plasma generating gases and/or plasma excited species, depending on use of the RPS 2001, may pass through a plurality of holes in faceplate 2017 for a more uniform delivery into the first plasma region 2015.

Exemplary configurations may include having the gas inlet assembly 2005 open into a gas supply region 2058 partitioned from the first plasma region 2015 by faceplate 2017 so that the gases/species flow through the holes in the faceplate 2017 into the first plasma region 2015. Structural and operational features may be selected to prevent significant backflow of plasma from the first plasma region 2015 back into the supply region 2058, gas inlet assembly 2005, and fluid supply system (not shown). The structural features may include the selection of dimensions and cross-sectional geometries of the apertures in faceplate 2017 to deactivate back-streaming plasma. The operational features may include maintaining a pressure difference between the gas supply region 2058 and first plasma region 2015 that maintains a unidirectional flow of plasma through the showerhead 2025. The faceplate 2017, or a conductive top portion of the chamber, and showerhead 2025 are shown with an insulating ring 2020 located between the features, which allows an AC potential to be applied to the faceplate 2017 relative to showerhead 2025 and/or ion suppressor 2023. The insulating ring 2020 may be positioned between the faceplate 2017 and the showerhead 2025 and/or ion suppressor 2023 enabling a capacitively coupled plasma (CCP) to be formed in the first plasma region. A baffle (not shown) may additionally be located in the first plasma region 2015, or otherwise coupled with gas inlet assembly 2005, to affect the flow of fluid into the region through gas inlet assembly 2005.

The ion suppressor 2023 may comprise a plate or other geometry that defines a plurality of apertures throughout the structure that are configured to suppress the migration of charged species (e.g., ions) out of the plasma excitation region 2015 while allowing uncharged neutral or radical species to pass through the ion suppressor 2023 into an activated gas delivery region between the suppressor and the showerhead. In disclosed embodiments, the ion suppressor 2023 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 2023 may provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity. In alternative embodiments in which deposition is performed, it can also shift the balance of conformal-to-flowable style depositions for dielectric materials, carbon-containing materials, and other materials.

The plurality of holes in the ion suppressor 2023 may be configured to control the passage of the activated gas, i.e., the ionic, radical, and/or neutral species, through the ion suppressor 2023. For example, the aspect ratio of the holes, or the hole diameter to length, and/or the geometry of the holes may be controlled so that the flow of ionically-charged species in the activated gas passing through the ion suppressor 2023 is reduced. The holes in the ion suppressor 2023 may include a tapered portion that faces the plasma excitation region 2015, and a cylindrical portion that faces the showerhead 2025. The cylindrical portion may be shaped and dimensioned to control the flow of ionic species passing to the showerhead 2025. An adjustable electrical bias may also be applied to the ion suppressor 2023 as an additional means to control the flow of ionic species through the suppressor.

The ion suppression element 2023 may function to reduce or eliminate the amount of ionically-charged species traveling from the plasma generation region to the substrate. Uncharged neutral and radical species may still pass through the openings in the ion suppressor to react with the substrate. It should be noted that the complete elimination of ionically-charged species in the reaction region surrounding the substrate is not always the desired goal. In many instances, ionic species are required to reach the substrate in order to perform the etch and/or deposition process. In these instances, the ion suppressor may help to control the concentration of ionic species in the reaction region at a level that assists the process.

Showerhead 2025 in combination with ion suppressor 2023 may allow a plasma present in chamber plasma region 2015 to avoid directly exciting gases in substrate processing region 2033, while still allowing excited species to travel from chamber plasma region 2015 into substrate processing region 2033. In this way, the chamber may be configured to prevent the plasma from contacting a substrate 2055 being etched. This may advantageously protect a variety of intricate structures and films patterned on the substrate, which may be damaged, dislocated, or otherwise warped if directly contacted by a generated plasma. Additionally, when plasma is allowed to contact the underlying material exposed by trenches, such as the etch stop, the rate at which the underlying material etches may increase.

The processing system may further include a power supply 2040 electrically coupled with the processing chamber to provide electric power to the faceplate 2017, ion suppressor 2023, showerhead 2025, and/or pedestal 2065 to generate a plasma in the first plasma region 2015 or processing region 2033. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 2015. This in turn may allow development of particular plasma characteristics such that precursors may be dissociated in specific ways to enhance the etching profiles produced by these precursors.

A plasma may be ignited either in chamber plasma region 2015 above showerhead 2025 or substrate processing region 2033 below showerhead 2025. A plasma may be present in chamber plasma region 2015 to produce radical-fluorine precursors from au inflow of a fluorine-containing precursor. An AC voltage typically in the radio frequency (RF) range may be applied between the conductive top portion of the processing chamber, such as faceplate 2017, and showerhead 2025 and/or ion suppressor 2023 to ignite a plasma in chamber plasma region 2015 during deposition. An RF power supply may generate a high RF frequency of 13.56 MHz but may also generate other frequencies alone or in combination with the 13.56 MHz frequency.

Plasma power can be of a variety of frequencies or a combination of multiple frequencies. In the exemplary processing system the plasma may be provided by RF power delivered to faceplate 2017 relative to ion suppressor 2023 and/or showerhead 2025. The RF power may be between about 10 watts and about 2000 watts, between about 100 watts and about 2000 watts, between about 200 watts and about 1500 watts, or between about 200 watts and about 1000 watts in different embodiments. The RF frequency applied in the exemplary processing system may be low RF frequencies less than about 200 kHz, high RF frequencies between about 10 MHz and about 15 MHz, or microwave frequencies greater than or about 1 GHz in different embodiments. The plasma power may be capacitively-coupled (CCP) or inductively-coupled (ICP) into the remote plasma region.

The top plasma region 2015 may be left at low or no power when a bottom plasma in the substrate processing region 2033 is turned on to, for example, cure a film or clean the interior surfaces bordering substrate processing region 2033. A plasma in substrate processing region 2033 may be ignited by applying an AC voltage between showerhead 2055 and the pedestal 2065 or bottom of the chamber. A cleaning gas may be introduced into substrate processing region 2033 while the plasma is present.

A fluid, such as a precursor, for example a fluorine-containing precursor, may be flowed into the processing region 2033 by embodiments of the showerhead described herein. Excited species derived from the process gas in the plasma region 2015 may travel through apertures in the ion suppressor 2023, and/or showerhead 2025 and react with an additional precursor flowing into the processing region 2033 from a separate portion of the showerhead. Alternatively, if all precursor species are being excited in plasma region 2015, no additional precursors may be flowed through the separate portion of the showerhead. Little or no plasma may be present in the processing region 2033. Excited derivatives of the precursors may combine in the region above the substrate and, on occasion, on the substrate to etch structures or remove species on the substrate in disclosed applications.

Exciting the fluids in the first plasma region 2015 directly, or exciting the fluids in the RPS unit 2001, may provide several benefits. The concentration of the excited species derived from the fluids may be increased within the processing region 2033 due to the plasma in the first plasma region 2015. This increase may result from the location of the plasma in the first plasma region 2015. The processing region 2033 may be located closer to the first plasma region 2015 than the remote plasma system (RPS) 2001, leaving less time for the excited species to leave excited states through collisions with other gas molecules, walls of the chamber, and surfaces of the showerhead.

The uniformity of the concentration of the excited species derived from the process gas may also be increased within the processing region 2033. This may result from the shape of the first plasma region 2015, which may be more similar to the shape of the processing region 2033. Excited species created in the RPS trait 2001 may travel greater distances in order to pass through apertures near the edges of the showerhead 2025 relative to species that pass through apertures near the center of the showerhead 2025. The greater distance may result in a reduced excitation of the excited species and, for example, may result in a slower growth rate near the edge of a substrate. Exciting the fluids in the first plasma region 2015 may mitigate this variation for the fluid flowed through RPS 2001.

The processing gases may be excited in the RPS unit 2001 and may be passed through the showerhead 2025 to the processing region 2033 in the excited state. Alternatively, power may be applied to the first processing region to either excite a plasma gas or enhance an already excited process gas from the RPS. While a plasma may be generated in the processing region 2033, a plasma may alternatively not be generated in the processing region. In one example, the only excitation of the processing gas or precursors may be from exciting the processing gases in the RPS unit 2001 to react with the substrate 2055 in the processing region 2033.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), mass flow controller (MFC), an injection valve, or by commercially available water vapor generators. The treatment gas may be introduced to the processing region 2033, either through the RPS unit or bypassing the RPS units, and may further be excited in the first plasma region.

FIG. 6B shows a detailed view of the features affecting the processing gas distribution through faceplate 2017. As shown in FIGS. 6A and 6B, faceplate 2017, cooling plate 2003, and gas inlet assembly 2005 intersect to define a gas supply region 2058 into which process gases may be delivered from gas inlet 2005. The gases may fill the gas supply region 2058 and flow to first plasma region 2015 through apertures 2059 in faceplate 2017. The apertures 2059 may be configured to direct flow in a substantially unidirectional manner such that process gases may flow into processing region 2033, but may be partially or fully prevented from backflow into the gas supply region 2058 after traversing the faceplate 2017.

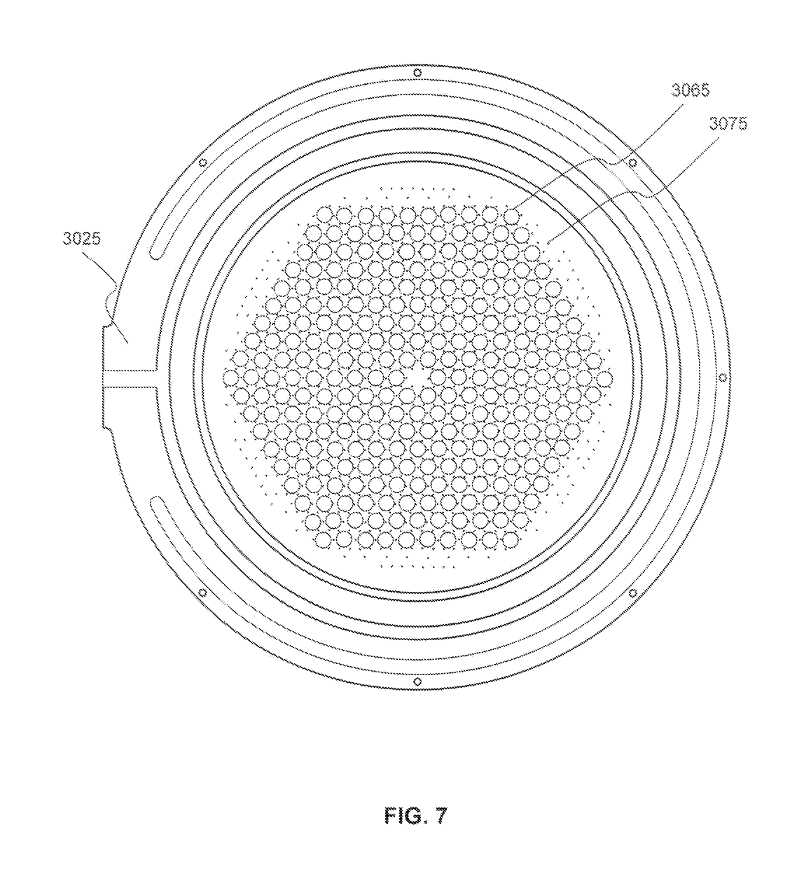

The gas distribution assemblies such as showerhead 2025 for use in the processing chamber section 2000 may be referred to as dual channel showerheads (DCSH) and are additionally detailed in the embodiments described in FIG. 6A as well as FIG. 7 herein. The dual channel showerhead may provide for etching processes that allow for separation of etchants outside of the processing region 2033 to provide limited interaction with chamber components and each other prior to being delivered into the processing region.

The showerhead 2025 may comprise an upper plate 2014 and a lower plate 2016. The plates may be coupled with one another to define a volume 2018 between the plates. The coupling of the plates may be so as to provide first fluid channels 2019 through the upper and lower plates, and second fluid channels 2021 through the lower plate 2016. The formed channels may be configured to provide fluid access from the volume 2018 through the lower plate 2016 via second fluid channels 2021 alone, and the first fluid channels 2019 may be fluidly isolated from the volume 2018 between the plates and the second fluid channels 2021. The volume 2018 may be fluidly accessible through a side of the gas distribution assembly 2025. Although the exemplary system of FIG. 6A includes a dual-channel showerhead, it is understood that alternative distribution assemblies may be utilized that maintain first and second precursors fluidly isolated prior to the processing region 2033. For example, a perforated plate and tubes underneath the plate may be utilized, although other configurations may operate with reduced efficiency or not provide as uniform processing as the dual-channel showerhead as described.

In the embodiment shown, showerhead 2025 may distribute via first fluid channels 2019 process gases which contain plasma effluents upon excitation by a plasma in chamber plasma region 2015 or from RPS unit 2001. In embodiments, the process gas introduced into the RPS unit 2001 and/or chamber plasma region 2015 may contain fluorine, e.g., CF₄, NF₃, or XeF₂, oxygen, e.g. N₂O, or hydrogen-containing precursors, e.g. H₂ or NH₃. One or both process gases may also include a carrier gas such as helium, argon, nitrogen (N₂), etc. Plasma effluents may include ionized or neutral derivatives of the process gas and may also be referred to herein as a radical-fluorine precursor, referring to the atomic constituent of the process gas introduced. In an example, a fluorine-containing gas, such as NF₃, may be excited in the RPS unit 2001 and passed through regions 2015 and 2033 without the additional generation of plasmas in those regions. Plasma effluents from the RPS unit 2001 may pass through the showerhead 2025 and then react with the substrate 2055. Alter passing through the showerhead 2025, plasma effluents may include radical species and may be essentially devoid of ionic species or UV light. These plasma effluents may react with films on the substrate 2055, e.g., titanium nitride and other masking material.

The gas distribution assemblies 2025 for use in the processing chamber section 2000 are referred to as dual channel showerheads (DCSH) and are detailed in the embodiments described in FIG. 7 herein. The dual channel showerhead may allow for flowable deposition of a material, and separation of precursor and processing fluids during operation. The showerhead may alternatively be utilized for etching processes that allow for separation of etchants outside of the reaction zone to provide limited interaction with chamber components and each other prior to being delivered into the processing region.

FIG. 7 is a bottom view of a showerhead 3025 for use with a processing chamber according to disclosed embodiments. Showerhead 3025 may correspond with the showerhead shown in FIG. 6A. Through-holes 3065, which show a view of first fluid channels 2019, may have a plurality of shapes and configurations in order to control and affect the flow of precursors through the showerhead 3025. Small holes 3075, which show a view of second fluid channels 2021, may be distributed substantially evenly over the surface of the showerhead, even among the through-holes 3065, which may help to provide more even mixing of the precursors as they exit the showerhead than other configurations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a trench” includes a plurality of such trenches, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor patterning method comprising:
forming a layer of masking material on regions of dielectric material above a semiconductor substrate;
forming a trench through the masking material, wherein the trench formation exposes at least a portion of the dielectric material;
forming a protective layer over the exposed portion of the dielectric material; and
removing the masking material.

2. The method of claim 1, wherein the trench is characterized by a sidewall and wherein forming the protective layer comprises forming a section of protective layer on the sidewall.

3. The method of claim 2, wherein:
the layer of masking material has a top surface and
the method comprises removing substantially all of the protective layer from the top surface of the layer of masking material while retaining a part of the section of protective layer on the sidewall.

4. The method of claim 2, wherein:
the sidewall comprises the dielectric material,
the sidewall has a profile,
and removing the masking material comprises retaining the profile of the sidewall.

5. The method of claim 2, wherein the method comprises removing substantially all of the section of protective layer from the sidewall.

6. The method of claim 1, wherein the masking material comprises titanium nitride.

7. The method of claim 1, wherein the protective layer comprises carbon.

8. The method of claim 1, wherein the protective layer formed is non-conformal.

9. The method of claim 1, wherein the dielectric material has a dielectric constant below about 3.0.

10. The method of claim 1, wherein forming the protective layer comprises:
striking a plasma in a substrate-processing region, and
flowing a carbon-containing gas through the plasma.

11. The method of claim 10, wherein the carbon-containing gas comprises methane or a fluorocarbon.

12. The method of claim 3, wherein removing substantially all of the protective layer from the top surface of the layer of masking material comprises:
striking a plasma in a substrate-processing region,
flowing a gas through the plasma to form an energized gas, and
reacting the energized gas with the protective layer.

13. The method of claim 12, wherein the gas comprises hydrogen and nitrogen.

14. The method of claim 13, wherein the gas comprises a mixture of H₂ and N₂.

15. The method of claim 13, wherein the gas does not comprise oxygen.

16. The method of claim 1, wherein removing the masking material comprises
striking a plasma in a region separated from the semiconductor substrate by a showerhead,
flowing a gas through the plasma and the showerhead to form plasma effluents, and
reacting tire plasma effluents with the masking material.

17. A semiconductor patterning method comprising:
forming a masking layer on top of underlying material, wherein the masking layer has a top surface;
forming a trench through the masking layer, wherein the formation of the trench exposes a portion of the underlying material;
forming a protective layer on the top surface of the masking layer;
removing a portion of the protective layer;
removing the masking layer by flowing a first gas through a remote plasma source and showerhead, wherein the removal of the masking layer retains substantially all of the portion of the underlying material.

18. The method of claim 17, wherein removal of the portion of the protective layer comprises:
striking a plasma in a substrate-processing region,
flowing a second gas through the plasma to form an energized gas, and
reacting the energized gas with the protective layer.

19. The method of claim 17, wherein:
the trench has a bottom, and
removing the portion of the protective layer comprises retaining a first section of the protective layer above the bottom of the trench and removing a second section of the protective layer on the top surface of the masking layer.

20. A method of patterning features on a semiconductor substrate, the method comprising:
forming a dielectric layer;
forming a mask layer above the dielectric layer, wherein
the mask layer has a top surface;
patterning the mask layer and the dielectric layer to form a trench in the dielectric layer, wherein:
the trench is characterized by a sidewall comprising dielectric material;
forming a carbon-containing protective layer on the top surface of the mask layer and on the sidewall of the trench, wherein the formation comprises:
striking a first plasma in a first substrate-processing region, and
flowing a carbon-containing gas through the first plasma;
removing substantially ail of the carbon-containing protective layer from the top surface of the mask layer while retaining a portion of the carbon-containing protective layer on the sidewall, wherein the portion of the carbon-containing protective layer covers substantially all of the sidewall and wherein removal comprises:
sinking a second plasma in a second substrate-processing region,
flowing a mixture of gases comprising hydrogen and nitrogen through the second plasma to form an energized mixture of gases, and
reacting the energized mixture of gases with the carbon-containing protective layer; and
removing the mask layer with a dry process while retaining the dielectric layer from the sidewall, wherein removal of the mask layer comprises:
striking a third plasma in a region separated from the semiconductor substrate by a showerhead,
flowing a fluorine-containing gas through the third plasma and showerhead to form plasma effluents, and
reacting the plasma effluents with the mask layer.
